(19) United States
(12) Patent Application Publication
(10) Pub. No.: US 2024/0203320 A1
(43) Pub. Date: Jun. 20, 2024

(54) SEMICONDUCTOR DEVICE AND ELECTRONIC TERMINAL

(71) Applicant: WUHAN CHINA STAR OPTOELECTRONICS TECHNOLOGY CO., LTD., Hubei (CN)

(72) Inventors: Zhou ZHANG, Wuhan (CN); Guowei ZHA, Wuhan (CN); Xialing LIU, Wuhan (CN)

(21) Appl. No.: 17/910,799

(22) PCT Filed: Aug. 30, 2022
(86) PCT No.: PCT/CN2022/115928

§ 371 Date: Sep. 10, 2022

(30) Foreign Application Priority Data
Jul. 8, 2022 (CN) 202210806370.9

(51) Int. Cl. G09G 3/32

(52) U.S. Cl. CPC G09G 3/32; G09G 2300/0842; G09G 2330/021; G09G 2330/045

(57) ABSTRACT

A semiconductor device and an electronic terminal are provided. The semiconductor device and the electronic terminal including an insulating substrate and a driving circuit positioned at least on one side of the insulating substrate. The driving circuit includes a plurality of functional modules and a plurality of power supply modules. Each of power supply modules is disposed close to and electrically connected to a corresponding functional module.

### FIELD OF INVENTION

The present application relates to a field of display technology, and in particular, to a technical field of display panel manufacturing, in particular to a semiconductor device and an electronic terminal.

### BACKGROUND OF INVENTION

The display panel can process electrical signals to display images and transmit information, and has become an indispensable part of life and work.

Currently, the functional modules in the display panel need to work under a power supply of the power supply module for data transmission and processing. However, the functional modules and power supply modules integrated on the silicon-based chip is limited by a cost and a size of the silicon-based chip. This leads to a centralized distribution of power supply modules and the need to supply power to multiple functional modules, resulting in a large amount of heat and slow heat dissipation in an area where the power supply modules are positioned in the silicon-based chip, which reduces a reliability of an operating performance of the silicon-based chip.

Therefore, the centralized distribution of the currently power supply modules integrated on the silicon-based chip causes the chip to dissipate heat slowly, which is in urgent need of improvement.

### SUMMARY OF INVENTION

Embodiments of the present application provide a semiconductor device and an electronic terminal, to solve a technical problem of slow heat dissipation of the silicon-based chip caused by a concentrated distribution of the currently power supply modules integrated on the silicon-based chip.

Embodiments of the present application provide a semiconductor device, including:
an insulating substrate; and
a driving circuit positioned at least on one side of the insulating substrate, wherein the driving circuit includes a plurality of functional modules and a plurality of power supply modules;
wherein each of the power supply modules is disposed close to and electrically connected to a corresponding functional module;
wherein at least one of the power supply modules includes:
a power supply assembly; and
a voltage regulation module electrically connected between the power supply assembly and the corresponding functional module;
wherein the voltage regulation module includes a switch assembly and a share assembly electrically connected to each other, and wherein the share assembly is configured to reduce a voltage or a current of the switch assembly; and
wherein the functional module and the power supply module are positioned on a same side or on different sides of the insulating substrate.

In one embodiment, the share assembly is arranged in parallel with the switch assembly, wherein the switch assembly is electrically connected to a positive electrode of the power supply assembly through a first node and is electrically connected to a negative electrode of the power supply assembly through a second node.

In one embodiment, the share assembly includes a plurality of shunt sub-assemblies arranged in parallel, and wherein at least one of the shunt sub-assemblies includes at least one of a resistance component and a switch component.

In one embodiment, at least one of the shunt sub-assemblies includes the switch component, and wherein the switch component and the switch assembly are closed simultaneously or alternately.

In one embodiment, the switch assembly includes a first transistor, wherein the switch component includes a second transistor, and wherein a gate electrode of the first transistor is electrically connected to a gate electrode of the second transistor.

Embodiments of the present application also provide a semiconductor device, including:
an insulating substrate; and
a driving circuit positioned at least on one side of the insulating substrate, wherein the driving circuit includes a plurality of functional modules and a plurality of power supply modules;
wherein each of the power supply modules is close to and electrically connected to a corresponding functional module.

In one embodiment, at least one of the power supply modules includes:
a power supply assembly; and
a voltage regulation module electrically connected between the power supply assembly and the corresponding functional module;
wherein the voltage regulation module includes a switch assembly and a share assembly electrically connected to each other, and wherein the share assembly is configured to reduce a voltage or a current of the switch assembly.

In one embodiment, the share assembly is arranged in parallel with the switch assembly, wherein the switch assembly is electrically connected to a positive electrode of the power supply assembly through a first node, and is electrically connected to a negative electrode of the power supply assembly through a second node.

In one embodiment, the share assembly includes a plurality of shunt sub-assemblies arranged in parallel, and wherein at least one of the shunt sub-assemblies includes any one of a resistance component and a switch component.

In one embodiment, at least one of the shunt sub-assemblies includes the switch component, and wherein the switch component and the switch assembly are closed simultaneously or alternately.

In one embodiment, the switch assembly includes a first transistor, wherein the switch component includes a second transistor, and wherein a gate electrode of the first transistor is electrically connected to a gate electrode of the second transistor.

In one embodiment, a plurality of the first nodes of the plurality of power supply modules are electrically connected to each other through a first grid wire, and wherein a plurality of the second nodes of the plurality of power supply modules are electrically connected to each other through a second grid wire.

In one embodiment, the functional module and the power supply module are positioned on a same side or on different sides of the insulating substrate.

In one embodiment, the insulating substrate includes a first substrate and a second substrate;
wherein both the functional module and the power supply module are positioned on a same side of the first substrate, and wherein the second substrate is positioned on a side of the functional module and the power supply module away from the first substrate; or
alternatively, the functional module and the power supply module are positioned on different sides of the first substrate, and wherein the second substrate is positioned on a side of the functional module or the power supply module away from the first substrate.

In one embodiment, the plurality of the functional modules includes a control module, a memory module, and an analog module.

Embodiments of the present application provide an electronic terminal, including the semiconductor device as described above.

In one embodiment, the electronic terminal further includes a panel main body, wherein the panel main body includes a display region and a non-display region, and wherein the panel main body includes:
a circuit layer includes a display circuit portion positioned in the display region and a driving circuit portion positioned in the non-display region, and wherein the driving circuit portion is electrically connected to the display circuit portion.

In one embodiment, the driving circuit portion includes a plurality of functional portions and a plurality of power supply portions;
wherein each of the power supply portions is close to and electrically connected to a corresponding functional portion.

In one embodiment, the display circuit portion includes a third transistor, wherein the driving circuit portion includes a fourth transistor, and wherein the fourth transistor and the third transistor have a same material and are set in a same layer.

In one embodiment, the display circuit portion includes a third transistor, wherein the driving circuit portion includes a resistance component, and wherein the resistance component and the third transistor are made of a same material and set in a same layer.

The semiconductor device and electronic terminal provided by the embodiments of the present application include an insulating substrate and a driving circuit positioned at least on one side of the insulating substrate. The driving circuit includes a plurality of functional modules and a plurality of power supply modules. Each of the power supply modules is disposed close to and electrically connected to a corresponding functional module. At least one electrical device of at least one functional module in the present application is arranged on the insulating substrate, so that the electrical devices in the driving circuit can be further distributed and arranged to reduce an accumulation of heat. At the same time, each power supply module is disposed close to and electrically connected to the corresponding functional module, which can effectively reduce a distance between the power supply module and the corresponding functional module, reduce a voltage drop loss caused by a long distance of the power supply, and improve a reliability of power supply of the plurality of power supply modules.

### DESCRIPTION OF FIGURES

The technical solutions and other beneficial effects of the present application will be apparent through the detailed description of the specific embodiments of the present application in conjunction with the accompanying figures.

FIG. 1 is a schematic top view of a semiconductor device provided by one embodiment of the present application.

FIG. 2 is a schematic block diagram of a structure of a driving circuit in the prior art.

FIG. 3 is a schematic circuit diagram of a functional module provided by one embodiment of the present application.

FIG. 4 is a schematic circuit diagram of a first type of electrical connection of a plurality of functional modules according to one embodiment of the present application.

FIG. 5 is a schematic circuit diagram of a second type of electrical connection of a plurality of functional modules according to one embodiment of the present application.

FIG. 6 is a schematic circuit diagram of a third type the electrical connection of a plurality of functional modules of according to one embodiment of the present application.

FIG. 7 is a schematic structural block diagram of the electrical connection of a plurality of functional modules according to one embodiment of the present application.

FIGS. 8 to 11 are schematic cross-sectional views of the semiconductor device provided by the embodiments of the present application.

FIG. 12 is a schematic top view of an electronic terminal provided by one embodiment of the present application.

### DETAILED DESCRIPTION OF EMBODIMENTS

The technical solutions in the embodiments of the present application will be clearly and continuously described below with reference to the accompanying figures in the embodiments of the present application. Obviously, the described embodiments are only a part of the embodiments of the present application, but not all of the embodiments. Based on the embodiments in the present application, all other embodiments obtained by those skilled in the art without inventive steps fall within a protection scope of the present application.

In the description of the present application, it should be understood that the orientation or positional relationship indicated by the terms “closer”, “farther away”, etc. is based on an orientation or positional relationship shown in the accompanying figures. It is only for a convenience of describing the present application and simplifying the description, rather than indicating or implying that the referred device or element must have a particular orientation, be constructed and operate in a particular orientation, it should not be construed as a limitation on the application. In addition, the terms “first”, “second”, etc. are used for descriptive purposes only, and should not be construed as indicating or implying relative importance or implying the number of indicated technical features. Thus, features defined as “first”, “second” may expressly or implicitly include one or more of said features. In the description of the present application, “plurality” means two or more, unless otherwise expressly and specifically defined.

Reference herein to an “embodiment” means that a particular feature, structure, or characteristic described in connection with the embodiment can be included in at least one embodiment of the present application. The appearances of the phrase in various places in the specification are not necessarily all referring to a same embodiment, nor a separate or alternative embodiment that is mutually exclusive of other embodiments. It is explicitly and implicitly understood by those skilled in the art that the embodiments described herein may be combined with other embodiments.

Embodiments of the present application provide a semiconductor device, including but not limited to the following embodiments and combinations of the following embodiments.

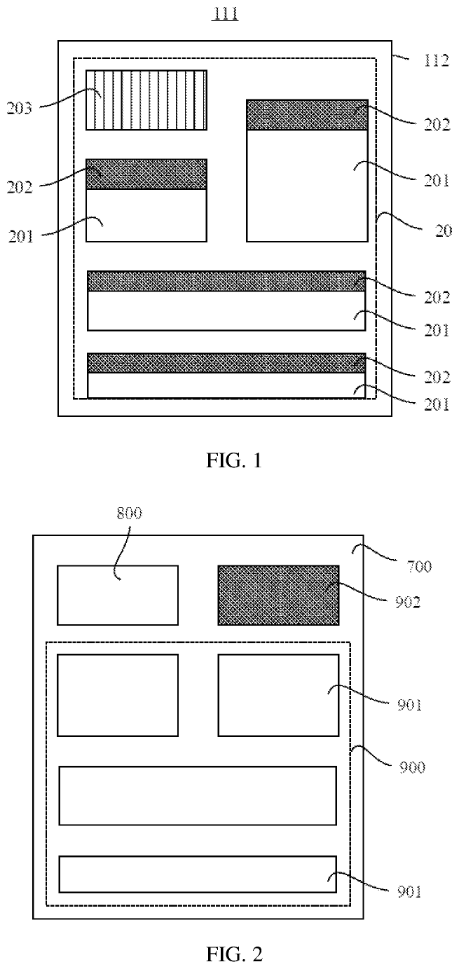

In one embodiment, as shown in FIG. 1, the semiconductor device 111 includes an insulating substrate 112 and a driving circuit 20. The driving circuit 20 is positioned at least on one side of the insulating substrate 112, and includes a plurality of functional modules 201 and a plurality of power supply modules 202. Each of the power supply modules 202 is disposed close to and electrically connected to a corresponding functional module 201.

It should be noted that, as shown in FIG. 2, due to a cost of the integrated driving chip and a cost of the silicon base 700 used to carry the driving circuit 900 to be integrated are high, generally, all functional modules 901 to be integrated in the interface 800 to be integrated and the driving circuit 900 to be integrated are integrated into a driving chip. At the same time, in order to save a size of the silicon base 700, the power supply modules 902 to be integrated are distributed centrally and supply power to all the functional modules 901 to be integrated, which causes a region where the power supply module 902 to be integrated in the driving chip has a large amount of heat, and the heat dissipation is slow, resulting in low reliability of an operating performance of the driving chip.

It can be understood that, in this embodiment, as shown in FIG. 1, a driving circuit is disposed on the insulating substrate 112, and including a plurality of functional modules 201 and a plurality of power supply modules 202. Compared with the embodiment shown in FIG. 2, due to a cost of the insulating substrate 112 is relatively low, a size of the insulating substrate 112 can be larger, so that the electrical devices in the driving circuit 20 can be further distributed and arranged to reduce an accumulation of heat. Further, as shown in FIG. 1, the driving circuit 20 is configured to include a plurality of functional modules 201 and a plurality of power supply modules 202. Compared with the embodiment shown in FIG. 2, in this embodiment, the originally separate power supply module 902 to be integrated is set as a plurality of functional modules 201 in a distributed manner to reduce the accumulation of heat. At the same time, each power supply module 202 is disposed close to and electrically connected to the corresponding functional module 201, which can effectively reduce a distance between the power supply module 202 and the corresponding functional module 201, reduce a voltage drop loss caused by the long distance in the power supply, and improve a reliability of power supply from a plurality of power supply modules 202.

It should be noted that the quantitative relationship between the functional modules 201 and the power supply modules 202 is not limited in this embodiment, as long as the number of either of the two is at least two. Of course, as shown in FIG. 1, the driving circuit 20 in this embodiment may also include an interface module 203 for the driving circuit 20 to exchange information with the outside world.

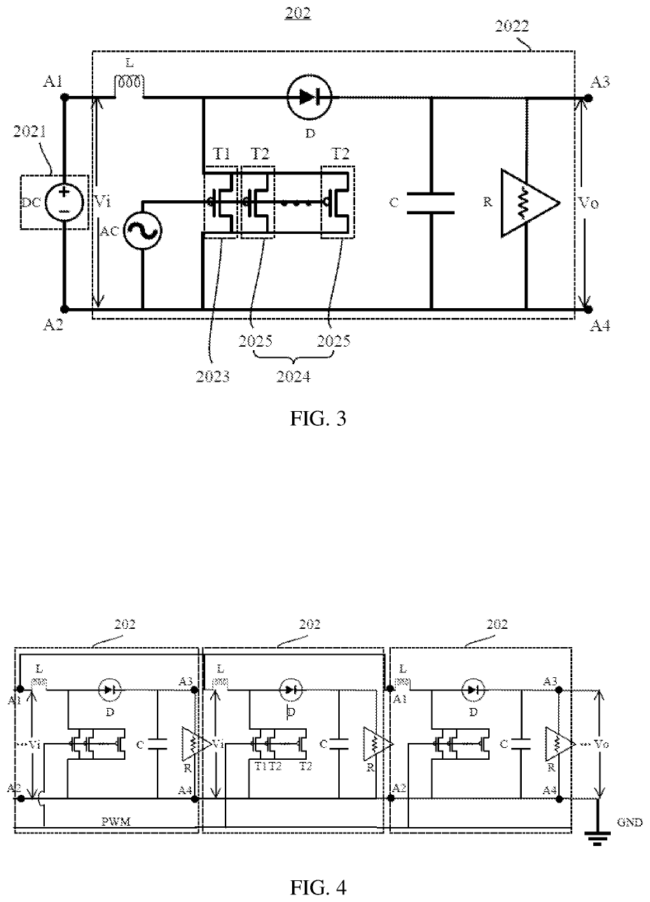

In one embodiment, as shown in FIG. 3, at least one of the power supply modules 202 includes a power supply assembly 2021 and a voltage regulation module 2022. The voltage regulation module 2022 is electrically connected between the power supply assembly 2021 and a corresponding functional module 201. The voltage regulation module 2022 includes a switch assembly 2023 and a share assembly 2024 electrically connected to each other. The share assembly 2024 is configured to reduce a voltage or a current of the switch assembly. It can be understood that the voltage regulation module 2022 in this embodiment includes the switch assembly 2023 and the share assembly 2024 that are electrically connected, so that when ensuring a magnitude of a main circuit current flowing through the switch assembly 2023 and the share assembly 2024 arranged in parallel is a certain magnitude to ensure a sufficient output voltage Vo, or when ensuring that a total voltage flowing through the switch assembly 2023 and the share assembly 2024 arranged in series is constant to ensure a sufficient output voltage Vo, compared with non-disposing the share assembly 2024, in this embodiment, the share assembly 2024 can share part of the main circuit current to reduce the current flowing through the switch assembly 2023, or share part of the voltage to reduce the voltage shared in the switch assembly 2023, thereby reducing a heat generation of the switch assembly 2023, and at the same time reducing a risk of burnout of the switch assembly 2023 and improves a reliability of the power supply module 202 in operation when avoiding reducing the output voltage Vo.

In one embodiment, as shown in FIG. 2 and FIG. 3, the share assembly 2024 is arranged in parallel with the switch assembly 2023 to reduce the current of the switch assembly 2023. The switch assembly 2023 is electrically connected to a positive electrode of the power supply assembly 2021 through a first node A1, and is electrically connected to a negative electrode of the power supply assembly 2021 through a second node A2. Specifically, the power supply module 202 may be, but not limited to, a direct current power supply DC. The direct current power supply DC may be loaded between the first node A1 and the second node A2 to supply power to the voltage regulation module 2022. The voltage regulation module 2022 may generate the output voltage Vo based on the voltage regulation module 2022, to make the functional module 201 can be connected to the voltage regulation module 2022 through the third node A3 and the fourth node A4, to make the functional module 201 to be loaded with the output voltage Vo to work.

It can be understood that the voltage regulation module 2022 in this embodiment includes a switch assembly 2023 and a share assembly 2024 arranged in parallel, so that when ensuring the magnitude of the main circuit current flowing through the switch assembly 2023 and the share assembly 2024 arranged in parallel is certain to ensure sufficient output voltage Vo, compared with non-paralleling the share assembly 2024, the share assembly 2024 in this embodiment can share part of the main circuit current to reduce the current flowing through the switch assembly 2023, thereby reducing a heat generation of the switch assembly 2023, and avoiding reducing the outputting the voltage Vo, reducing a risk of burnout of the switch assembly 2023, and improving the operation reliability of the power supply module 202.

A specific structure of the share assembly 2024 is not limited in this embodiment. For example, the share assembly 2024 may include a plurality of electrical devices arranged in series, a plurality of devices arranged in parallel, or a plurality of electrical devices connected in other connection manners. It only needs to satisfy that part of the main circuit current can be shared to reduce the current flowing through the switch assembly 2023.

In one embodiment, as shown in FIG. 3, the share assembly 2024 includes a plurality of shunt sub-assemblies 2025 arranged in parallel. At least one of the shunt sub-assemblies 2025 includes any of a resistance component and a switch component. It can be understood that, in combination with the above discussion, in this embodiment, at least one of the resistance component and the switch component is arranged in parallel with the switch assembly 2023, so that part of the main circuit current can be shared to reduce the current flowing through the switch assembly 2023, so as to reduce a risk of burnout of the switch assembly 2023. Specifically, the specific types and parameters of the resistance component and the switch component are not limited here. Here, at least one shunt sub-assembly 2025 includes a resistance component, and at least one shunt sub-assembly 2025 includes a switch component as an example for explanation. At least the resistance component can share part of the main circuit current to reduce the current flowing through the switch assembly 2023 when the switch assembly 2023 is closed, and further, if the switch component is also closed, both the switch component and the resistance component can share part of the main circuit current to further reduce the current flowing through the switch assembly 2023.

In one embodiment, as shown in FIG. 3, at least one of the shunt sub-assemblies 2025 includes the switch component. The switch component and the switch assembly 2023 are closed simultaneously or alternately. Specifically, in this embodiment, the switch component and the switch assembly 2023 arranged in parallel are essentially switches, and can have two states of on and off. The specific types of the switch component and the switch assembly 2023 are not limited here.

It can be understood that, in combination with the above discussion, for example, when the switch component and the switch assembly 2023 are closed at the same time, the closed switch component has a corresponding resistance value. In combination with the above discussion, the switch component can simultaneously share part of the main circuit current to further reduce the flow through the switch assembly 2023. For example, when the switch component and the switch assembly 2023 are alternately closed, the closed switch component or the switch assembly 2023 forms a path to allow current to pass, and the open switch component or the switch assembly 2023 forms an open circuit without current passing through. That is, the switch component and the switch assembly 2023 can alternately allow current to pass through, thereby avoiding high frequency or continuous heat build-up due to the current passing through the two.

It should be noted that, in conjunction with the above discussion, the simultaneous closing of the switch component and the switch assembly 2023 can be achieved by both being controlled by a same signal on a same wire (refer to FIG. 4), and the alternate closing of the switch component and the switch assembly 2023 can be achieved through both controlled by different signals on different wires.

In one embodiment, as shown in FIG. 3, the switch assembly 2023 includes a first transistor T1. The switch component includes a second transistor T2. A gate electrode of the first transistor T1 is electrically connected to a gate electrode of the second transistor T2 so that the corresponding switch component and the corresponding switch assembly 2023 are closed simultaneously. Specifically, this embodiment does not limit the types and materials of the first transistor T1 and the second transistor T2. For example, both the first transistor T1 and the second transistor T2 can be closed within a first voltage range. The gate electrode of T1 and the gate electrode of the second transistor T2 are electrically connected, and the gate electrode of the first transistor T1 and the gate electrode of the second transistor T2 can be loaded with a same signal, so that the corresponding switch component and the corresponding switch assembly 2023 can be simultaneously closed. In conjunction with the discussion above, the switch components may simultaneously share a portion of the main current to further reduce the current flowing through the switch assembly 2023.

It should be noted that the first transistor T1 and the second transistor T2 can also be closed in different voltage ranges. At this time, the gate electrode of the first transistor T1 and the gate electrode of the second transistor T2 are electrically connected to load a same signal, which can realize the first transistor T1 and the second transistor T2 are not turned on simultaneously or even alternately.

The functions and specific structures of the plurality of power supply modules 202 are not limited in the present application. For example, as shown in FIG. 3, the power supply module 202 is used as an example of a booster circuit for description. The switch assembly 2023 includes a first transistor T1. The switch component includes a second transistor T2. The gate electrode of the first transistor T1 and the gate electrode of the second transistor T2 are electrically connected to the alternating current power supply AC. Here, it is taken as an example that the alternating current power supply AC can control the first transistor T1 and the second transistor T2 to be turned on and off at the same time as an example. For example, the alternating current power supply AC can provide a PWM signal, the inductor L can be connected between the first node A1 and the switch assembly 2023 and the share assembly 2024 arranged in parallel. A capacitor C can be connected with a resistor R in parallel. A diode D can be connected between the inductor L and the capacitor C and the resistor R arranged in parallel. During a charging process, the first transistor T1 and the plurality of second transistors T2 can be equivalent to a wire, the current generated by the DC power supply DC flows through the inductor L, the diode D prevents the capacitor C from discharging to the ground, and the current in the inductor L increased linearly at a certain ratio, which is related to a magnitude of the inductor L. With an increase of current of the inductor L, some energy is stored in the inductor L. During a discharge process, the first transistor T1 and a plurality of second transistors T2 can be disconnected, due to the current retention characteristics of the inductor L, the current flowing through the inductor L will not immediately become 0, but will slowly change from a value when the charging is completed to 0. The original circuit has been disconnected, so the inductor L only can be discharged through the new circuit, that is, the inductor L begins to charge the capacitor C, and the voltage across the capacitor C is increased. It should be noted that in order to make an entire inertial system continue, the currents in the charging process and the discharging process must be equal. According to the current equation, a relationship between the output voltage Vo and the input voltage Vi can be obtained as Vo=Vi*/(1−D). D is a duty cycle of a corresponding PWM signal.

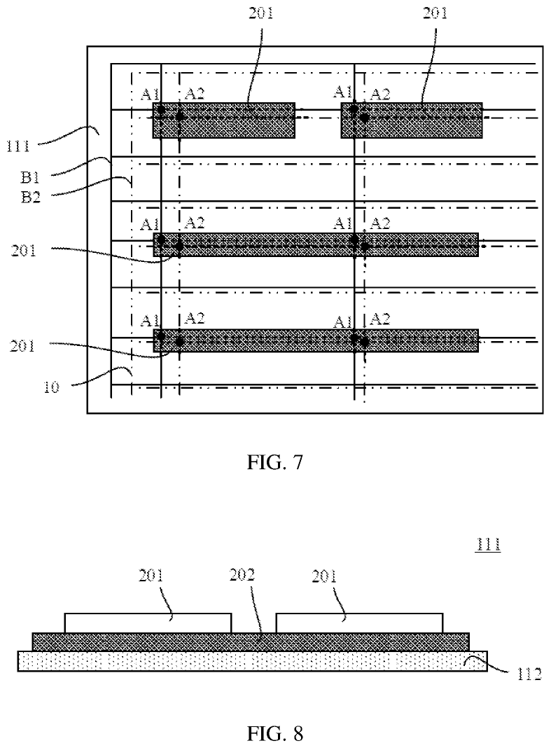

In one embodiment, as shown in FIG. 4 to FIG. 7, the plurality of first nodes A1 of the plurality of power supply modules 202 are electrically connected to each other through a first grid wire B1. A plurality of the second nodes A2 of the plurality of power supply modules 202 are electrically connected to each other through a second grid wire B2. It can be understood that, in combination with the above discussion, among the plurality of power supply modules 202, at least one power supply module 202 includes a power supply assembly 2021 to supply power to the voltage regulation module 2022. Based on this, further, in this embodiment, the plurality of first nodes A1 of the plurality of power supply modules 202 are connected through the first grid wire B1, and the plurality of second nodes A2 of the plurality of power supply modules 202 are connected through the second grid wire B2, which can be avoided that on a premise of configuring a corresponding power supply assembly 2021 for each power supply module 202, a corresponding input voltage Vi between the first node A1 and the second node A2 of each power supply module 202 is achieved through the first grid wire B1 and the second grid wire B2. In addition, due to a reduction in the number of power supply assembly 2021 and the grid-like distribution of the first grid wire B1 and the second grid wire B2 on an entire surface, a distribution of the current can be evened out to reduce a risk of uneven heat dissipation from the heat generated by the current.

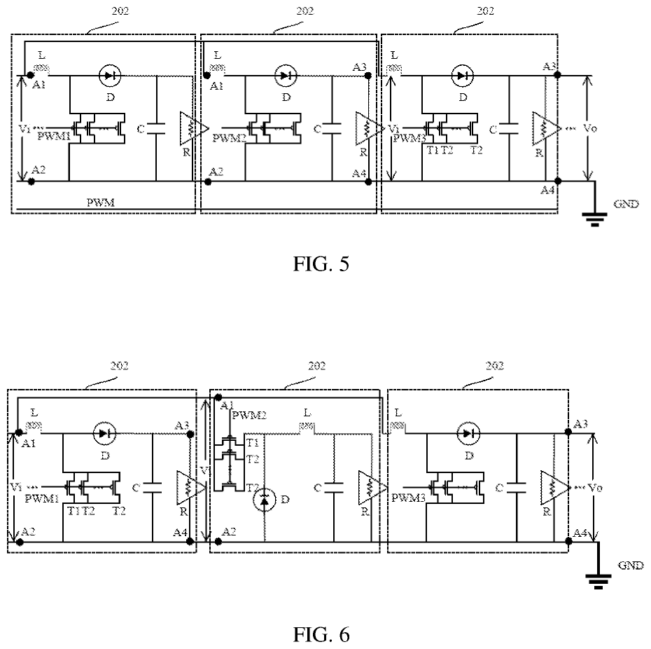

With reference to FIG. 3, FIGS. 4 to 6, a plurality of power supply modules 202 positioned in a same row and continuously arranged are taken as an example for description. The plurality of first nodes A1 corresponding to the plurality of power supply modules 202 can be electrically connected through a single wire in the first grid wire B1, and is electrically connected to the positive electrode of the power supply assembly 2021 through the corresponding first node A1 of the power supply module 202 which is positioned at a terminal portion. Further, in a same way, the corresponding plurality of second nodes A2 and the corresponding plurality of fourth nodes A4 of the plurality of power supply modules 202 can be electrically connected through a single wire of the second grid wire B2, and electrically connected to the negative electrode of power supply assembly 2021 (ie, connected to the ground wire GND) through the corresponding second node A2 or the fourth node A4 of the power supply module 202 which is positioned at the terminal portion. Still further, as shown in FIG. 4, the gate electrodes of the corresponding first transistors T1 and the gate electrodes of the second transistors T2 of the plurality of power supply modules 202 can be electrically connected through wires to load a same PWM signal. As shown in FIG. 5 and FIG. 6, the gate electrode of the corresponding first transistor T1 and the gate electrodes of the plurality of second transistors T2 of each power supply module 202 can be loaded with corresponding PWM signal. A plurality of PWM signals provided to the plurality of power supply modules 202 can be different.

With reference to FIG. 3, FIGS. 4 to 6, the two first nodes A1 corresponding to the two power supply modules 202 positioned in two adjacent rows may be electrically connected through the grid-shaped portion of the first grid wire B1, and is electrically connected to a positive electrode of the power supply assembly 2021 through a corresponding first node A1 of the power supply module 202 positioned at the terminal portion. Similarly, the two second nodes A2 corresponding to the two power supply modules 202 positioned in two adjacent rows can be electrically connected through the grid-shaped portion of the second grid wire B2, and can be electrically connected to the negative electrode of the power supply assembly 2021 (ie, connected to the ground line GND) through the corresponding second node A2 of the power supply module 202 at the terminal portion.

It should be noted that the present application does not limit the functions and types of the plurality of power supply modules 202. The plurality of power supply modules 202 may include at least one of a boost circuit, a buck circuit, a buck-boost circuit, and a switched capacitor voltage converter. Further, the present application does not limit the specific structures of the booster circuit, the buck circuit, the buck-boost circuit, and the switched capacitor voltage converter. Specifically, the boost circuit may refer to, but not limited to, the circuit shown in FIG. 4. The step-down circuit may refer to, but not limited to, the middle one of the power supply modules 202 in the circuit shown in FIG. 8. Similarly, according to the current equation, a relationship between the output voltage Vo and the input voltage Vi is obtained as Vo=Vi*/D, D is a duty cycle of the corresponding PWM signal. A relationship between the output voltage Vo and the input voltage Vi in the buck-boost circuit is Vo=−Vi*D/(1−D), D is the duty cycle of the corresponding PWM signal. The above equations are all based on the electrical connection between the gate electrode of the first transistor T1 and the corresponding gate electrodes of all the second transistors T2.

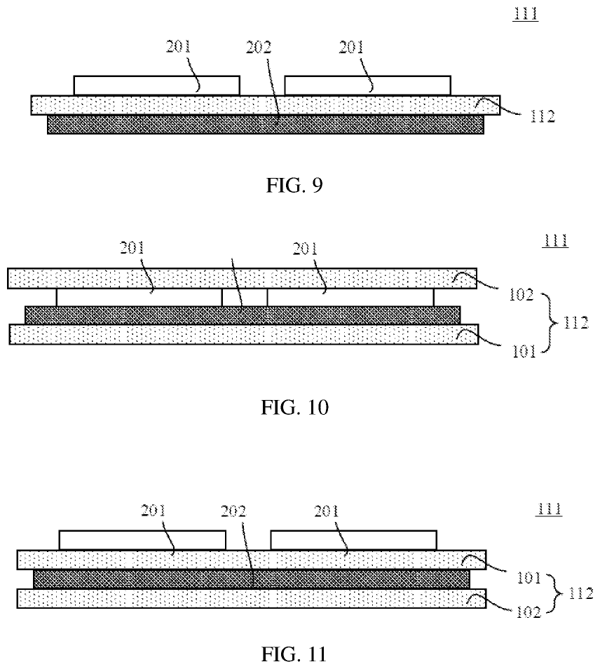

In one embodiment, as shown in FIG. 1, FIG. 8, and FIG. 9, the functional module 201 and the power supply module 202 are positioned on a same side or on different sides of the insulating substrate 112. The insulating substrate 112 may be, but not limited to, a rigid substrate (eg, glass) or a flexible substrate (eg, polyimide). Specifically, as shown in FIG. 8, when the functional module 201 and the power supply module 202 are positioned on a same side of the first substrate 101, an insulating layer may be provided between the functional module 201 and the power supply module 202 to insulate the functional module 201 and the power supply module 202. As shown in FIG. 9, when the functional module 201 and the power supply module 202 are positioned on different sides of the first substrate 101, the functional module 201 and the power supply module 202 can be insulated by the first substrate 101. Further, the functional module 201 and the power supply module 202 can realize the wire connection of the relevant line through a through hole process or a side wiring process.

In one embodiment, as shown in FIG. 1, FIG. 10, and FIG. 11, the insulating substrate 112 includes a first substrate 101 and a second substrate 102. As shown in FIG. 10, the functional module 201 and the power supply module 202 are positioned on a same side of the first substrate 101, and the second substrate 102 is positioned on a side of the functional module 201 and the power supply module 202 away from the first substrate 101; or, as shown in FIG. 11, the functional module 201 and the power supply module 202 are positioned on different sides of the first substrate 101, and the second substrate 102 is positioned on a side of the functional module 201 or the power supply module 202 far away the first substrate 101.

Specifically, as shown in FIG. 10, the first substrate 101 and the second substrate 102 form an accommodation space to encapsulate an upper and a lower side of the functional module 201 and the power supply module 202, thereby improving a reliability of the encapsulation. Also as shown in FIG. 11, by disposing the first substrate 101 to support the functional module 201 and disposing the second substrate 102 to support the power supply module 202, a reliability of the support is improved.

It should be noted that, in the above embodiments, the relative positions of the film layer where the functional module 201 is positioned and the film layer where the power supply module 202 is positioned are not limited, and a number of functional modules 201 and a number of power supply modules 202 are also not limited. Further, the power supply module 202 can be configured to include two sub-power supply modules 202 that are stacked and connected by wires, so as to reduce an impedance of the power supply module 202 and thereby reducing power loss. It is not limited whether the two sub-power supply modules 202 are positioned on a same side of the first substrate 101 or the second substrate 102.

In one embodiment, as shown in FIG. 1, the plurality of functional modules 201 include a control module, a storage module and an analog module. Further, the driving circuit 20 may also include a sensing module. The control module can realize a control of the storage module, the simulation module, and the sensing module. The storage module can realize a storage of data in at least one of the control module, the simulation module, and the sensing module. It should be noted that the functions and specific structures of the above functional modules are not limited in this embodiment.

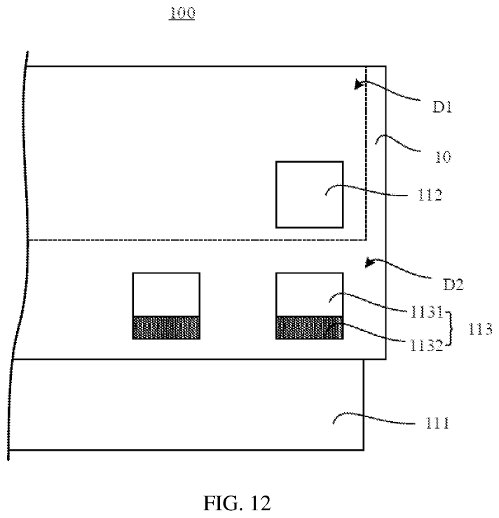

One embodiment of the present application provides an electronic terminal. As shown in FIG. 12, the electronic terminal 100 includes the semiconductor device 111 described in any of the above.

In one embodiment, as shown in FIG. 12, the electronic terminal 100 further includes a panel main body 10. The panel main body 10 includes a display region D1 and a non-display region D2. The panel main body 10 includes a circuit layer including a display circuit portion 112 in the display region D1 and a driving circuit portion 113 in the non-display region D2. The driving circuit portion 113 is electrically connected to the display circuit portion 112. Specifically, the display circuit portion 112 may include a pixel driving circuit that is electrically connected to a plurality of sub-pixels positioned in the display region D1. The driving circuit portion 113 may include, but is not limited to, a gate driving circuit electrically connected to a plurality of gate lines positioned in the display region D1, a demultiplexer or other circuits electrically connected between the semiconductor device and the display circuit portion 112.

In one embodiment, as shown in FIG. 12, the driving circuit portion 113 includes a plurality of functional portions 1131 and a plurality of power supply portions 1132. Each of the power supply portions 1132 is disposed close to and electrically connected to a corresponding one of the functional portions 1131. The plurality of power supply portions 1132 in the driving circuit portion 113 can supply power to the plurality of functional portions 1131. Specifically, for the power supply portion 1132 in this embodiment, reference may be made to the above discussion on the power supply module 202, and the functional portion 1131 can refer to the above discussion about the functional module 201. For example, a specific circuit structure of the power supply portion 1132 can be the same as a specific circuit structure of the power supply module 202 in FIG. 3, and FIG. 4 to FIG. 6.

It can be understood that in this embodiment, as shown in FIG. 1, on a basis of the semiconductor device 111, the driving circuit portion 113 including a plurality of functional portions 1131 and a plurality of power supply portions 1132 is provided in the circuit of the panel main body 10. Compared with the embodiment shown in FIG. 2, since a size of the non-display region D2 in the panel main body 10 is larger, in other words, the non-display region D2 in the panel main body 10 can share the number of electrical devices integrated on the silicon base 700, so that at least the electrical devices in the driving circuit portion 113 can be further dispersed and arranged to reduce an accumulation of heat. Similarly, further, as shown in FIG. 12, the driving circuit portion 113 includes a plurality of functional portions 1131 and a plurality of power supply portions 1132. Compared with the embodiment shown in FIG. 2, in this embodiment, an originally separate power supply module 902 to be integrated is set as a plurality of power supply portions 1132 arranged in a distributed manner to reduce an accumulation of heat. At the same time, each of the plurality of power supply portions 1132 is disposed close to and electrically connected to a corresponding functional portion 1131, which can effectively reduce a distance between the power supply portion 1132 and the corresponding functional portion 1131, and reduce a voltage loss of the power supply caused by the long distance, and improve the reliability of power supply by the plurality of power supply portions 1132. Similarly, it should be noted that a quantitative relationship between the functional portions 1131 and the power supply portions 1132 is not limited in this embodiment, as long as the number of either one of the two is at least 2.

In one embodiment, as shown in FIG. 12 and FIG. 3, the display circuit portion 112 includes a third transistor. The driving circuit portion 113 includes a fourth transistor. The fourth transistor and the third transistor have a same material and are set in a same layer. With reference to a specific circuit structure of the power supply module 202 in FIG. 3 and FIGS. 4 to 6, the fourth transistor of the driving circuit portion 113 can be configured as the same as at least one of switch component and switch assembly 2023 of the power supply module 202 in the driving circuit portion 113. Specifically, in combination with the above discussion, in the power supply module 202, the switch assembly 2023 may include the first transistor T1, and the switch component may include the second transistor T2. Further, in this embodiment, the device in the driving circuit portion 113 that is the same as at least one of the first transistor T1 and at least one of the second transistor T2 in the power supply module 202 can be made by a same material and a same layer as the third transistor. For example, the active layers, the gate electrode layers, and the source-drain electrode layers of the device that is the same as at least one of the first transistor T1 and the second transistor T2 in the driving circuit portion 113 and the third transistor can be manufactured in a same layer and made of a same material, to save manufacturing process and improve manufacturing efficiency.

In one embodiment, as shown in FIG. 12 and FIG. 3, the display circuit portion 112 includes a third transistor. The driving circuit portion 113 includes a resistance component. The resistance component is made of a same material and manufactured in a same layer as part of the third transistor. Specifically, with reference to the above discussion, in the power supply module 202, at least one of shunt sub-assemblies 2025 may include a resistance component. Further, in this embodiment, the device in the driving circuit portion 113 that is the same as the resistive component in the power supply module 202 and a part of the third transistor can be arranged in a same layer, and the materials of the two are the same. Specifically, in combination with the above discussion, the third transistor may include an active layer, a gate electrode layer, and a source-drain electrode layer. The device in the driving circuit portion 113 that is the same as the resistance component in the power supply module 202 may be disposed in a same layer and made of a same material as at least one of the active layer, the gate electrode layer, and the source-drain electrode layer. Further, the device in the driving circuit portion 113 that is the same as the resistance component in the power supply module 202 can be arranged in a same layer and made of a same material as the active layer. The present embodiment does not limit a composition material of the active layer of the third transistor, which may be, but not limited to, metal oxide or polysilicon.

The semiconductor device and electronic terminal provided by the embodiments of the present application include an insulating substrate and a driving circuit positioned at least on one side of the insulating substrate. The driving circuit includes a plurality of functional modules and a plurality of power supply modules. Each of the power supply modules is disposed close to and electrically connected to a corresponding functional module. At least one electrical device of at least one functional module in the present application is arranged on the insulating substrate, so that the electrical devices in the driving circuit can be further distributed and arranged to reduce an accumulation of heat. At the same time, each power supply module is disposed close to and electrically connected to the corresponding functional module, which can effectively reduce a distance between the power supply module and the corresponding functional module, reduce a voltage drop loss caused by a long distance of the power supply, and improve a reliability of power supply of the plurality of power supply modules.

The semiconductor devices and electronic terminals provided by the embodiments of the present application have been introduced in detail above. The principles and implementations of the present application are described in this article by using specific examples. The descriptions of the above embodiments are only used to help understand the technology, the solution, and the core idea of the present application. Those of ordinary skill in the art should understand that they can still make modifications to the technical solutions described in the foregoing embodiments, or perform equivalent replacements to some of the technical features. These modifications or replacements do not make an essence of the corresponding technical solutions deviates from a scope of the technical solutions of the embodiments of the present application.

What is claimed is:

1. A semiconductor device, comprising:
an insulating substrate; and
a driving circuit positioned at least on one side of the insulating substrate, wherein the driving circuit comprises a plurality of functional modules and a plurality of power supply modules;
wherein each of the power supply modules is disposed close to and electrically connected to a corresponding functional module;
wherein at least one of the power supply modules comprises:
a power supply assembly; and
a voltage regulation module electrically connected between the power supply assembly and the corresponding functional module;
wherein the voltage regulation module comprises a switch assembly and a share assembly electrically connected to each other, and wherein the share assembly is configured to reduce a voltage or a current of the switch assembly; and
wherein the functional module and the power supply module are positioned on a same side or on different sides of the insulating substrate.

2. The semiconductor device according to claim 1, wherein the share assembly is arranged in parallel with the switch assembly, and wherein the switch assembly is electrically connected to a positive electrode of the power supply assembly through a first node and is electrically connected to a negative electrode of the power supply assembly through a second node.

3. The semiconductor device according to claim 2, wherein the share assembly comprises a plurality of shunt sub-assemblies arranged in parallel, and wherein at least one of the shunt sub-assemblies comprises any one of a resistance component and a switch component.

4. The semiconductor device according to claim 3, wherein at least one of the shunt sub-assemblies comprises the switch component, and wherein the switch component and the switch assembly are closed simultaneously or alternately.

5. The semiconductor device according to claim 4, wherein the switch assembly comprises a first transistor, wherein the switch component comprises a second transistor, and wherein a gate electrode of the first transistor is electrically connected to a gate electrode of the second transistor.

6. A semiconductor device, comprising:
an insulating substrate; and
a driving circuit positioned at least on one side of the insulating substrate, wherein the driving circuit comprises a plurality of functional modules and a plurality of power supply modules;
wherein each of the power supply modules is disposed close to and electrically connected to a corresponding functional module.

7. The semiconductor device according to claim 6, wherein at least one of the power supply modules comprises:
a power supply assembly; and
a voltage regulation module electrically connected between the power supply assembly and the corresponding functional module;
wherein the voltage regulation module comprises a switch assembly and a share assembly electrically connected to each other, and wherein the share assembly is configured to reduce a voltage or a current of the switch assembly.

8. The semiconductor device according to claim 7, wherein the share assembly is arranged in parallel with the switch assembly, and wherein the switch assembly is electrically connected to a positive electrode of the power supply assembly through a first node and is electrically connected to a negative electrode of the power supply assembly through a second node.

9. The semiconductor device according to claim 8, wherein the share assembly comprises a plurality of shunt sub-assemblies arranged in parallel, and wherein at least one of the shunt sub-assemblies comprises any one of a resistance component and a switch component.

10. The semiconductor device according to claim 9, wherein at least one of the shunt sub-assemblies comprises the switch component, and wherein the switch component and the switch assembly are closed simultaneously or alternately.

11. The semiconductor device according to claim 10, wherein the switch assembly comprises a first transistor, wherein the switch component comprises a second transistor, and wherein a gate electrode of the first transistor is electrically connected to a gate electrode of the second transistor.

12. The semiconductor device according to claim 8, wherein a plurality of the first nodes of the plurality of power supply modules are electrically connected to each other through a first grid wire, and wherein a plurality of the second nodes of the plurality of power supply modules are electrically connected to each other through a second grid wire.

13. The semiconductor device according to claim 6, wherein the functional module and the power supply module are positioned on a same side or on different sides of the insulating substrate.

14. The semiconductor device according to claim 6, wherein the insulating substrate comprises a first substrate and a second substrate;
wherein both the functional module and the power supply module are positioned on a same side of the first substrate, and wherein the second substrate is positioned on a side of the functional module and the power supply module away from the first substrate; or
alternatively, the functional module and the power supply module are positioned on different sides of the first substrate, and wherein the second substrate is positioned on a side of the functional module or the power supply module away from the first substrate.

15. The semiconductor device according to claim 6, wherein the plurality of the functional modules comprises a control module, a memory module, and an analog module.

16. An electronic terminal comprising the semiconductor device according to claim 6.

17. The electronic terminal according to claim 16, further comprising a panel main body, wherein the panel main body comprises a display region and a non-display region, and wherein the panel main body comprises:
a circuit layer comprises a display circuit portion positioned in the display region and a driving circuit portion positioned in the non-display region, wherein the driving circuit portion is electrically connected to the display circuit portion.

18. The electronic terminal according to claim 17, wherein the driving circuit portion comprises a plurality of functional portions and a plurality of power supply portions; and
wherein each of the power supply portions is disposed close to and electrically connected to a corresponding functional portion.

19. The electronic terminal according to claim 17, wherein the display circuit portion comprises a third transistor, wherein the driving circuit portion comprises a fourth transistor, and wherein the fourth transistor and the third transistor have a same material and are set in a same layer.

20. The electronic terminal according to claim 17, wherein the display circuit portion comprises a third transistor, wherein the driving circuit portion comprises a resistance component, and wherein the resistance component and the third transistor are made of a same material and set in a same layer.
